(19) United States
(12) Patent Application Publication
(10) Pub. No.: US 2025/0313729 A1
(43) Pub. Date: Oct. 9, 2025

(54) ADHESIVE PROTECTIVE FILM, OPTICAL MEMBER COMPRISING THE SAME, AND OPTICAL DISPLAY APPARATUS COMPRISING THE SAME

(71) Applicant: SAMSUNG SDI CO., LTD., Yongin-si (KR)

(72) Inventors: Ju Yeol Choi, Suwon-si (KR); Ji Hye Lee, Suwon-si (KR); Won Kim, Suwon-si (KR); Il Jin Kim, Suwon-si (KR); Kyung Hyun Song, Suwon-si (KR)

(21) Appl. No.: 19/169,456

(22) Filed: Apr. 3, 2025

(30) Foreign Application Priority Data
Apr. 3, 2024 (KR) 10-2024-0045098

(51) Int. Cl. C09J 7/38; G02B 1/14

(52) U.S. Cl. CPC C09J 7/385; G02B 1/14

(57) ABSTRACT

An adhesive protective film, an optical member including the adhesive protective film, and an optical display apparatus including the optical member. The adhesive protective film includes a cured product of a composition including a (meth)acrylic copolymer, a curing agent, an aromatic group-containing mono- or higher functional monomer, and a photoinitiator. The adhesive protective film has an initial peel strength of 7 gf/inch or less relative to a polyimide ash-containing surface configured to be attached thereto, and a peel strength of 200 gf/inch or more relative to the polyimide ash-containing surface upon light irradiation.

### CROSS-REFERENCE TO RELATED APPLICATION

This application claims priority and the benefit of Korean Patent Application No. 10-2024-0045098, filed on Apr. 3, 2024 in the Korean Intellectual Property Office, the entire disclosure of which is incorporated herein by reference.

### BACKGROUND

### (a) Field

The present disclosure relates to an adhesive protective film, an optical member, and an optical display apparatus.

### (b) Description of the Related Art

In a conventional device, in an optical member or an electronic member, a protective film, composed of an adhesive layer alone or a protective film composed of a base film and an adhesive layer, is attached to a surface of the device to prevent scratches thereon during certain processes, such as processing, assembly, inspection, and the like. Such a protective film is used by removing a release film from the adhesive layer. In recent years, optical members such as organic light emitting diode (OLED) devices have been replacing liquid crystal devices. In addition, flexible OLED devices are increasing in the art.

Unlike liquid crystal devices or typical OLED devices, flexible OLED devices, due to their flexibility, require a process protective film to protect an OLED panel from surface scratches during processing, assembly, inspection, and the like. The process protective film requires low peel strength and reworkability as well as being capable of ease of removal upon generation of defects, such as cosmetic abnormalities or foreign matter, during panel inspection. A P-film (patterned film) is permanently attached to the panel to support the panel while protecting the panel from moisture or an external environment is required after inspection. Since the P-film must be permanently attached to the panel, the P-film requires high peel strength and reliability.

Accordingly, since a typical panel manufacturing process requires a low peel strength process protective film, which is used temporarily, and a high peel strength P-film, which requires high peel strength, there is a need for processes including (i) process protective film attachment; (ii) process protective film removal, and (iii) P-film attachment.

In recent years, cost reduction and process optimization have been ongoing. Due to these ongoing efforts, the process protective film is patterned by a laser when used as a process protective film before UV irradiation. Here, when initial peel strength of the protective film with respect to a polyimide substrate is greater than a certain predetermined degree, deterioration in yield may happen due to a decrease in peeling success rate. Therefore, there is a need to provide a protective adhesive film that has low peel strength when stacked on the polyimide substrate and exhibits high peel strength after UV irradiation in order to incorporate the process protective film into the P-film.

Background information of the present disclosure can be found for example in Japanese Patent Registration No. 5,683,369 and the like.

### SUMMARY

It is an object of the present disclosure to provide an adhesive protective film that exhibits excellent peeling performance when attached to a polyimide-based optical device having polyimide ash.

It is an object of the present disclosure to provide an adhesive protective film that can be secured to a polyimide-based optical device having polyimide ash with greater peel strength after light irradiation than before light irradiation to improve durability of the optical device.

It is an object of the present disclosure to provide an adhesive protective film that prevents generation of bubbles when attached to a polyimide-based optical device having polyimide ash.

It is an object of the present disclosure to provide an adhesive protective film that can be used both as a temporary protective film for processes on a flexible light emitting device panel substrate and as a protective film for pattern reinforcement that can be selectively peeled off to form a pattern.

An aspect of the present disclosure relates to an adhesive protective film for polyimide-based optical devices containing polyimide ash.

In an embodiment, the adhesive protective film includes a cured product of a composition including a (meth)acrylic copolymer, a curing agent, an aromatic group-containing mono- or higher functional monomer, and a photoinitiator, wherein the adhesive protective film has an initial peel strength of 7 gf/inch or less with respect to a polyimide ash-containing surface and a peel strength of 200 gf/inch or more with respect to the polyimide ash-containing surface after the adhesive protective film attached to the polyimide ash-containing surface is subjected to light irradiation.

Another aspect of the present disclosure relates to an adhesive protective film.

In an embodiment, the adhesive protective film includes a cured product of a composition including a (meth)acrylic copolymer, a curing agent, an aromatic group-containing mono- or higher functional monomer, and a photoinitiator. The adhesive protective film has an initial peel strength of 7 gf/inch or less relative to a polyimide ash-containing surface configured to be attached thereto, and a peel strength of 200 gf/inch or more relative to the polyimide ash-containing surface upon light irradiation.

An aspect of the present disclosure relates to an optical member.

In an embodiment, the optical member includes: a polyimide-based optical device containing a polyimide ash on at least one surface thereof and an adhesive layer formed on the polyimide ash-containing surface, the adhesive layer including a photo-cured product of the adhesive protective film.

In an embodiment, the optical member includes a polyimide-based optical device, The polyimide-based optical device includes a polyimide ash-containing surface including a polyimide ash on at least one surface of the polyimide-based optical device; and an adhesive layer layered to the polyimide ash-containing surface. The adhesive layer includes the adhesive protective film.

An aspect of the present disclosure relates to an optical display apparatus.

In an embodiment, the optical display apparatus includes a cured product of the adhesive protective film or the optical member.

Embodiments of the present disclosure provide an adhesive protective film that exhibits excellent peeling performance when attached to a polyimide-based optical device having polyimide ash.

Embodiments of the present disclosure provide an adhesive protective film that can be secured to a polyimide-based optical device having polyimide ash with much higher peel strength after light irradiation than before light irradiation to improve durability of the optical device.

Embodiments of the present disclosure provide an adhesive protective film that prevents generation of bubbles when attached to a polyimide-based optical device having polyimide ash.

Embodiments of the present disclosure provide an adhesive protective film that can be used both as a temporary protective film for processes on a flexible light emitting device panel substrate and as a protective film for pattern reinforcement that can be selectively peeled off to form a pattern.

### BRIEF DESCRIPTION OF THE DRAWINGS

FIG. 1 is a flow diagram showing a method of forming a polyimide layer having polyimide ash according to an embodiment of the present disclosure.

FIG. 2 is a flow diagram showing a method of forming a polyimide layer having polyimide ash according to an embodiment of the present disclosure.

FIG. 3 is a schematic diagram showing a laser irradiation process during fabrication of a polyimide layer having polyimide ash according to an embodiment of the present disclosure.

FIG. 4 is a flow diagram showing a process of evaluating peeling performance according to an embodiment of the present disclosure.

FIG. 5 is a cross-sectional view of an optical member according to an embodiment of the present disclosure.

### DETAILED DESCRIPTION

Hereinafter, exemplary embodiments of the present disclosure will be described in detail with reference to the accompanying drawings such that the present disclosure can be easily implemented by a person having ordinary knowledge in the art. It should be understood that the present disclosure may be embodied in various ways and is not limited to the following embodiments. To facilitate understanding of the disclosure, the attached drawings are not drawn to actual scale and the dimensions of some components may be exaggerated. Furthermore, the same reference numbers may be assigned to the same components in different embodiments.

To illustrate the relationship of one element or feature to another element(s) or feature(s) as shown in a drawing, for ease of description, spatially relative terms such as “beneath,” “below,” “lower,” “above,” “upper,” etc. may be used herein. Spatial relative position will be understood to encompass different directions of the device in use or operation in addition to the direction depicted in the figures. For example, if the device in the drawing is turned over, elements described as “below” or “lower” other elements are understood to be “above” or “upper” other elements. Accordingly, the term “down” may encompass both upward and downward directions.

The terminology used herein is for the purpose of describing exemplary embodiments and is not intended to limit the present disclosure. Terms and words used in this specification and claims should not be construed as limited to their usual or dictionary meanings. Rather, the terms and words should be construed based on the principle that the inventor can appropriately define the concept of the term in order to explain his or her invention in the best way, and the terms and words must be interpreted with a meaning and concept consistent with the technical idea of the present disclosure. Since the embodiments described in the specification and the configurations shown in the drawings are merely the most preferable some embodiment and configurations of the present disclosure, they do not represent all of the technical ideas of the present disclosure, and it should be understood that various equivalents and modified examples, which may replace the embodiments, are possible.

As used herein, “comprise, include,” and/or “comprising, including” specifies the presence of the mentioned figures, numbers, steps, actions, members, elements and/or groups of these, and does not exclude the presence or addition of one or more other shapes, numbers, operations, members, elements and/or groups.

Although the first, second, etc. are used to describe various components, it goes without saying that these components are not limited by these terms. These terms are only used to distinguish one component from another component, and unless specifically stated to the contrary, the first component may also be a second component.

As used herein, the singular forms “a”, “an”, and “the” are intended to include the plural forms as well, unless the context specifically indicates otherwise.

As used herein, “(meth)acryl” refers to acryl and/or methacryl.

As used herein, “copolymer” may include a polymer or a resin.

As used herein, “glass transition temperature” may refer to a glass transition temperature (Tg) measured on a target monomer using a DSC Discovery (TA Instruments). Specifically, a homopolymer of the target monomer is heated to 180° C. at a heating rate of 20° C./min, is slowly cooled to −100° C., and is heated again to 100° C. at a heating rate of 10° C./min to obtain data of an endothermic transition curve. An inflection point of the endothermic transition curve may be defined as the glass transition temperature of the target monomer.

As used herein, to represent a specific numerical range, “X to Y” means a value greater than or equal to X and less than or equal to Y (i.e., X≤ and ≤Y).

An adhesive protective film according to the present disclosure can be in a state prior to light irradiation and may be provided in the form of an adhesive layer.

The adhesive protective film can be configured for adhesive protection for a polyimide-based optical device including a polyimide ash-containing surface before light irradiation. In addition, the adhesive protective film can be configured to improve durability of the polyimide-based optical device after light irradiation. The adhesive protective film can be an adhesive protective film having peel strength variable by light irradiation.

Specifically, the adhesive protective film can be attached to the polyimide ash-containing surface configured to temporarily protect the polyimide ash-containing surface. As a result, the adhesive protective film can be configured to prevent generation of scratches on the polyimide ash-containing surface during certain processes, such as processing, assembly, inspection, and the like. In particular, the adhesive protective film can be attached to the polyimide ash-containing surface and can be configured to prevent bubble generation.

After the adhesive protective film is attached to and patterned on the polyimide ash-containing surface, the adhesive protective film, having enhanced peeling performance, can be peeled off of the polyimide ash-containing surface and/or an optical device.

The adhesive protective film can be an adhesive film having variable peel strength by adjusting light irradiation and can be adhered with greater peel strength to the polyimide ash-containing surface after light irradiation than before light irradiation, thereby improving durability of the polyimide-based optical device.

As used herein, the “polyimide-based optical device” refers to a polymer film processed by polymerization from a polyamic acid precursor. The polyimide-based optical device can include imide and aromatic groups in repeat units, has excellent mechanical properties and heat resistance properties, and can be used as a substrate of a flexible OLED panel.

In an embodiment, the polyimide-based optical device can be provided in a form of a polyimide layer containing a surface containing a polyimide ash.

A method of forming a polyimide layer including a polyimide ash-containing surface is described in the following.

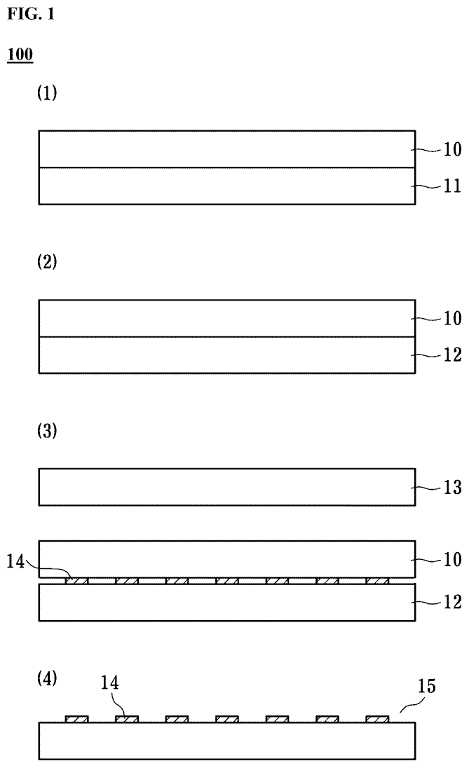

FIG. 1 is a flow diagram showing a method 100 of forming a polyimide layer having polyimide ash according to an embodiment of the present disclosure.

Referring to FIG. 1, (1) a polyimide varnish is deposited until a predetermined thickness is met on a lower surface of a glass plate 10 to form a polyimide varnish coat 11.
(2) The polyimide varnish coat 11 is dried and cured to form a polyimide layer 12 on the lower surface of the glass plate 10.
(3) The glass plate 10 is irradiated with a laser beam emitted from a laser irradiator 13 placed above the glass plate, thereby forming polyimide ash 14 on an upper surface of the polyimide layer 12.

Laser irradiation can form the polyimide ash by contacting (e.g., burning) a portion of the polyimide layer. The polyimide ash may, for example, refer to fine irregularities in the form of dust, which may form a fine step between a laser-treated portion and a non-laser treated portion. This step can facilitate delamination of the glass plate in step (4) shown in the following. The extent to which the polyimide ash 14 is formed or the area ratio of the polyimide ash 14 (ratio of the total area of the polyimide ash to the total area of the polyimide layer) can be adjusted depending on the type of polyimide varnish, the total thickness of the polyimide layer, the degree of irradiation with laser beams, and the like.
(4) The glass plate 10 can be removed from the polyimide layer 12, thereby providing a polyimide layer 15 that includes a surface containing the polyimide ash 14.

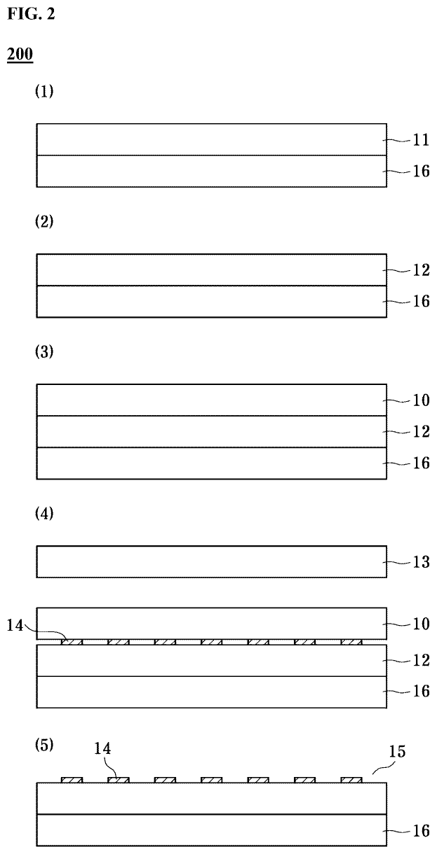

FIG. 2 is a flow diagram showing a method 200 of forming a polyimide layer having polyimide ash according to an embodiment of the present disclosure.

Referring to FIG. 2, (1) a polyimide varnish is deposited until a predetermined thickness is met on an upper surface of a release base film 16 to form a polyimide varnish coat 11.
(2) The polyimide varnish coat 11 is dried and cured to form a polyimide layer 12 on the upper surface of the release base film 16.
(3) A glass plate 10 is disposed on an upper surface of the polyimide layer 12.
(4) The glass plate 10 is irradiated with a laser beam emitted from a laser irradiator 13 placed above the glass plate, thereby forming polyimide ash 14 on the upper surface of the polyimide layer 12.

Laser treatment can form the polyimide ash by contacting (e.g., burning) a portion of the polyimide layer. The polyimide ash may refer to fine irregularities in the form of dust, which may form a fine step between a laser-treated portion and a non-laser treated portion. This step can facilitate delamination of the glass plate in step (5) shown in the following. The extent to which the polyimide ash 14 is formed or the area ratio of the polyimide ash 14 (ratio of the total area of the polyimide ash to the total area of the polyimide layer) can be adjusted depending on the type of polyimide varnish, the total thickness of the polyimide layer, the degree of irradiation with laser beams, and the like.
(5) The glass plate 10 can be removed from the polyimide layer 12, thereby providing a laminate of a polyimide layer 15 having the polyimide ash 14 on a surface thereof and the release base film 16.

The release base film 16 can be subjected to release treatment with silicone and the like and thus can be easily removed.

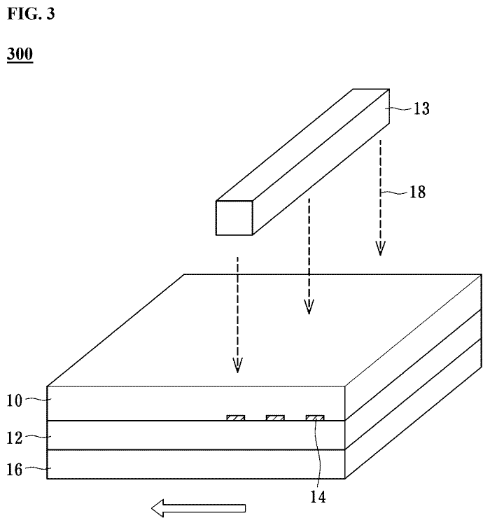

FIG. 3 is a schematic diagram showing a laser irradiation process 300 during formation of a polyimide layer having polyimide ash according to an embodiment of the present disclosure.

Referring to FIG. 3, a laminate is prepared according to an embodiment of the present disclosure. A polyimide layer 12 and a glass plate 10 are sequentially stacked on an upper surface of a release base film 16. Polyimide ash 14 is formed on an upper surface of the polyimide layer 12 by irradiating the laminate with one or more laser beams 18 using a laser irradiation device 13 from above an upper surface of the glass plate 10. The laminate is conveyed in a certain direction (towards the left hand side of FIG. 3) and the polyimide ash 14 can be discontinuously formed on the upper surface of the polyimide layer 12 by intermittent laser irradiation.

The glass plate can be an alkali-free glass plate and can have a thickness of 1 mm to 2 mm.

The polyimide varnish may include 90 wt % or more of at least one of a polyimide copolymer, a polyimide oligomer, and a polyimide monomer, without being limited thereto. For example, the polyimide varnish can include SD Flex (DuPont), without being limited thereto.

The polyimide varnish can be deposited by any typical method known to those skilled in the art. For example, the polyimide varnish can be deposited by a doctor blade coating method. In this method, the gauge may have a diameter of 0.5 mm to 1.0 mm, for example, 0.65 mm. The polyimide varnish can be deposited up to a thickness of 20 μm to 30 μm.

The polyimide varnish coat can be dried and cured to form a polyimide layer.

Drying may include heat treatment at 50° C. to 200° C. for 5 min to 60 min. Heat treatment may be performed once, twice or more. In one embodiment, heat treatment can be performed twice or more. For example, drying may include a first heat treatment at 50° C. to 100° C. for 5 min to 30 min and a second heat treatment at 100° C. to 200° C. for 5 min to 30min. Preferably, the first heat treatment is performed at 80° C. for 10 min and the second heat treatment is performed at 120° C. for 20 min.

A dried product of the polyimide varnish coat may have a thickness of 20 μm to 30 μm, preferably 20 μm.

Curing may include heat treatment at a greater temperature for an extended period of time than drying. Such a heat treatment can form a polyimide layer through imidization of the dried product of the polyimide varnish coat. Heat treatment may include heat treatment at a temperature of greater than 200° C. and less than or equal to 400° C. for 30 min to 120 min. In one embodiment, heat treatment may be performed once or more. Preferably, curing includes heat treatment at 250° C. for 60 min.

The polyimide layer may have a thickness of 20 μm to 30 μm, preferably 20 μm.

Laser irradiation may include irradiation at a dose of 100 mJ/cm² to 500 mJ/cm², for example, 150 mJ/cm² to 200 mJ/cm². In this range, the polyimide ash product can be capable of being easily peeled off of the glass plate. Laser irradiation may include light irradiation at a wavelength of 308 nm and may occur at picosecond, nanosecond, or femtosecond timescales.

The adhesive protective film, having enhanced peeling performance, can be attached to and patterned on the polyimide ash-containing surface and then peeled off of the polyimide ash-containing surface and/or an optical device.

As used herein, “enhanced peeling performance” means not only that, when the patterned adhesive protective film is peeled off of the polyimide ash-containing surface, the patterned adhesive protective film is peeled off without deformation of the polyimide ash-containing surface or the polyimide-based optical device including the polyimide ash-containing surface, but also that only portions to be peeled off are selectively peeled off at the same time without dragging between the portions to be peeled off and portions not to be peeled off, which are formed by patterning. According to one embodiment, the portions to be peeled and the portions not to be peeled can be alternately placed.

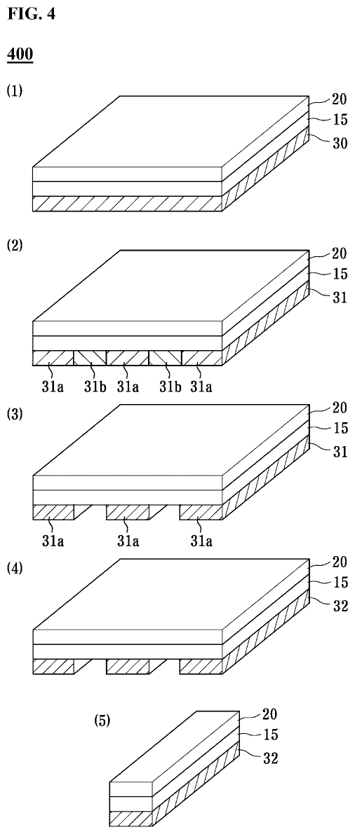

FIG. 4 is a flow diagram illustrating a process 400 of evaluating peeling performance.

Referring to FIG. 4, (1) a laminate is prepared according to an embodiment of the present disclosure. A polyimide layer 15 includes a polyimide ash-containing surface. The polyimide layer 15 and an optical device or optical film 20 are sequentially stacked on an upper surface of an adhesive protective film 30. Although not shown in FIG. 4, a lower surface of the polyimide layer 15 is the polyimide ash-containing surface.
(2) The adhesive protective film 30 of the laminate is patterned by a predetermined method to form a patterned adhesive protective film 31. By patterning, the adhesive protective film 31 is divided into portions 31a not to be peeled off and portions 31b to be peeled off.
(3) The portions 31b to be peeled off are peeled off of the adhesive protective film 31. According to an embodiment, the portions 31b to be peeled off can be peeled off by a method known to those skilled in the art.
(4) At least one surface of the adhesive protective film 31 is irradiated with light to cure the portions 31a not to be peeled off, thereby forming a photo-cured patterned adhesive protective film 32 on the lower surface of the polyimide layer 15.
(5) By cutting, an optical device or optical film 20, a polyimide layer 15 including a polyimide ash-containing surface, and a photo-cured patterned adhesive protective film 32 are prepared.

Peeling performance refers to a degree that, when the patterned adhesive protective film 30 in (2) and (3) of FIG. 4 is peeled off from the polyimide ash-containing surface, not only is the patterned adhesive protective film peeled off without deformation of the polyimide ash-containing surface or the polyimide-based optical device including the polyimide ash-containing surface, but also only the portions 31b to be peeled off are selectively peeled off at the same time without dragging between the portions 31b to be peeled off and the portions 31a not to be peeled off.

An adhesive protective film according to an embodiment of the present disclosure is described in the following.

The adhesive protective film includes a cured product of a composition including a (meth)acrylic copolymer, a curing agent, an aromatic group-containing mono- or higher functional monomer, and a photoinitiator, wherein the adhesive protective film may have an initial peel strength of 7 gf/inch or less with respect to a polyimide ash-containing surface and a peel strength of 200 gf/inch or more with respect to the polyimide ash-containing surface after the adhesive protective film is attached to the polyimide ash-containing surface and is subjected to light irradiation.

The adhesive protective film may have an initial peel strength of 7 gf/inch or less with respect to the polyimide ash-containing surface. In this range, when the patterned adhesive protective film, having enhanced peeling performance, is peeled off of the polyimide ash-containing surface, the patterned adhesive protective film can be peeled off without deformation of the polyimide ash-containing surface or the polyimide-based optical device including the polyimide ash-containing surface, and the portions to be peeled off can be selectively peeled off at the same time without dragging between the portions to be peeled off and the portions not to be peeled off, which are formed by patterning. For example, the adhesive protective film may have an initial peel strength of greater than 0 gf/inch and less than or equal to 7 gf/inch, for example, 1 gf/inch to 7 gf/inch, or 4 gf/inch to 7 gf/inch.

As used herein, “initial peel strength” refers to peel strength before irradiation with light.

The adhesive protective film has a peel strength of 200 gf/inch or more with respect to the polyimide ash-containing surface after the adhesive protective film is attached to the polyimide ash-containing surface and is subjected to light irradiation. In this range, the polyimide-based optical device containing the polyimide ash can exhibit good durability. For example, the adhesive protective film may have a post-irradiation peel strength of 300 gf/inch or more, for example, 300 gf/inch to 600 gf/inch.

As used herein, “light irradiation” may include irradiation at a wavelength of 280 nm to 430 nm, specifically at a wavelength of 350 nm to 390 nm, and at a dose of 1,000 mJ/cm². UV irradiation may be performed by at least one of a UV LED, a high-pressure mercury lamp, and a metal halide lamp.

In an embodiment, the adhesive protective film is a peel strength-enhancing adhesive protective film that exhibits significant increase in peel strength after light irradiation, in comparison with before light irradiation. Because the adhesive protective film according to the present disclosure has increased peel strength after light irradiation, the adhesive protective film attached to the polyimide-based optical device can provide permanent protection of the polyimide-based optical device after light irradiation. Therefore, the adhesive protective film according to the present disclosure can provide both temporary protection and permanent protection of the polyimide-based optical device and can be used as both a temporary protective film for certain processes and a protective film for reinforcement, thereby achieving process simplification, economic feasibility, and environmental friendliness. The temporary protective film for certain processes can be a film that is temporarily attached to an adherend and then removed therefrom, and can be a film that temporarily protects the polyimide-based optical device. The protective film for reinforcement can be a film that is permanently attached to the polyimide-based optical device to protect the polyimide-based optical device from an external environment and is not configured to be removed from the polyimide-based optical device.

The adhesive protective film can be used as a protective film for reinforcement. The protective film for reinforcement refers to a protective film stacked on at least one surface of a flexible panel to protect the flexible panel from external impact or the like.

In an embodiment, the adhesive protective film has a peel strength increase rate of 65 or more, as calculated according to Equation 1. In this range, the adhesive protective film can be attached to the polyimide-based optical device with enhanced peel strength and enhanced reliability after light irradiation, thereby providing an adhesive effect to the polyimide-based optical device.

Peel strength increase rate=P2/P1, <Equation 1>

where P1 is initial peel strength (unit: gf/inch) of the adhesive protective film with respect to the polyimide ash-containing surface, measured on a specimen of the adhesive protective film and a polyimide-based optical device including the polyimide ash-containing surface, and

P2 is peel strength (unit: gf/inch) of the adhesive protective film with respect to the polyimide ash-containing surface after light irradiation of the specimen.

Preferably, the adhesive protective film has a peel strength increase rate of 65 to 200, or 65 to 100, as calculated according to Equation 1. In this range, the adhesive protective film can easily secure the above range of initial peel strength and peel strength after light irradiation.

The adhesive protective film includes a cured product of a composition including a (meth)acrylic copolymer, a curing agent, an aromatic group-containing mono- or higher functional monomer, and a photoinitiator. The curing agent includes an isocyanate curing agent. The isocyanate curing agent is present in an amount of 6 parts by weight or more relative to 100 parts by weight of the (meth)acrylic copolymer. In an embodiment, the cured product may be a thermally cured product In an embodiment, the adhesive protective film can include the aromatic group-containing mono- or higher functional monomer and the photoinitiator dispersed in a matrix of the adhesive protective film formed by heat curing of the (meth)acrylic copolymer and the isocyanate curing agent.

### (Meth)Acrylic Copolymer

The (meth)acrylic copolymer is configured to form the matrix of the adhesive protective film and can be cured by the isocyanate curing agent to secure the initial peel strength of the adhesive protective film. The (meth)acrylic copolymer may also be configured to improve modulus and cohesion of the adhesive protective film together with the aromatic group-containing mono- or higher functional monomer after light irradiation.

The (meth)acrylic copolymer may have a glass transition temperature (Tg) of −10° C. or less, specifically −60° C. to −20° C. In this range, the (meth)acrylic copolymer can be configured to provide wettability (adhesion) to the polyimide-based optical device and initial peel strength of the adhesive protective film, and can be configured to increase peel strength after light irradiation by suppressing shrinkage of the adhesive protective film through adjustment of the glass transition temperature, as compared with an oligomer formed of a mono- or higher functional monomer.

The (meth)acrylic copolymer may have a weight average molecular weight of 500,000 g/mol or more, specifically 600,000 g/mol to 1,500,000 g/mol. In this range, the (meth)acrylic copolymer can be configured to provide wettability (adhesion) to an adherend and initial peel strength of the adhesive protective film.

The (meth)acrylate copolymer can include a copolymer of a monomer mixture including an alkyl group-containing (meth)acrylate monomer and a hydroxyl group-containing (meth)acrylate monomer.

The alkyl group-containing (meth)acrylic monomer is configured to form the matrix of the adhesive protective film and can include an unsubstituted C₁ to C₂₀, specifically C₂ to C₁₁, alkyl group-containing (meth)acrylic acid ester.

For example, the alkyl group-containing (meth)acrylic monomer can include at least one of methyl (meth)acrylate, ethyl (meth)acrylate, propyl (meth)acrylate, n-butyl (meth)acrylate, t-butyl (meth)acrylate, iso-butyl (meth)acrylate, pentyl (meth)acrylate, hexyl (meth)acrylate, heptyl (meth)acrylate, ethylhexyl (meth)acrylate, octyl (meth)acrylate, isooctyl (meth)acrylate, nonyl (meth)acrylate, decyl (meth)acrylate, and lauryl (meth)acrylate.

The alkyl group-containing (meth)acrylic monomer can be present in an amount of 85 mol % to 99.5 mol %, specifically 90 mol % to 98 mol %, or more specifically 95 mol % to 99 mol %, of the monomer mixture. In this range, it can be effective for the alkyl group-containing (meth)acrylic monomer to provide wettability to an adherend and initial peel strength of the adhesive protective film.

The hydroxyl group-containing (meth)acrylic monomer can be a (meth)acrylate containing at least one hydroxyl group. For example, the hydroxyl group-containing (meth)acrylate can include at least one of 2-hydroxyethyl (meth)acrylate, 3-hydroxypropyl (meth)acrylate, 4-hydroxybutyl (meth)acrylate, hydroxyhexyl (meth)acrylate, 1,4-cyclohexanedimethanol mono(meth)acrylate, 1-chloro-2-hydroxypropyl (meth)acrylate, diethylene glycol mono (meth)acrylate, 1,6-hexanediol mono (meth)acrylate, pentaerythritol tri(meth)acrylate, dipentaerythritol penta (meth)acrylate, neopentyl glycol mono(meth)acrylate, trimethylolpropane di (meth)acrylate, trimethylolethane di(meth)acrylate, 2-hydroxy-3-phenyloxypropyl (meth)acrylate, 4-hydroxycyclopentyl (meth)acrylate, 4-hydroxycyclohexyl (meth)acrylate, and cyclohexanedimethanol mono(meth)acrylate.

The hydroxyl group-containing (meth)acrylic monomer can be present in an amount of 0.1 mol % to 10 mol %, specifically 0.5 mol % to 10 mol %, 0.5 mol % to 5 mol %, 2 mol % to 10 mol %, or 1 mol % to 5 mol %, of the monomer mixture. In this range, it can be effective for the hydroxyl group-containing (meth)acrylic monomer to impart cohesion to the adhesive layer to form an adhesive layer and to provide initial peel strength of the adhesive protective film.

The monomer mixture can include a (meth)acrylic monomer having a homopolymer glass transition temperature of −80° C. to 0° C., specifically −60° C. to −20° C. In this range, the monomer mixture can be configured to facilitate preparation of the (meth)acrylic copolymers having the above range of the glass transition temperature.

In an embodiment, the monomer mixture can include 90 mol % or more, 95 mol % or more, or 95 mol % to 99 mol %, of the (meth)acrylic monomer having a homopolymer glass transition temperature of −80° C. to 0° C., specifically −60° C. to −20° C. In this range, the monomer mixture can be configured to easily secure the effects of the present disclosure. Such a monomer can include n-butyl acrylate or the like.

In an embodiment, the monomer mixture can be free from an aromatic group-containing monomer. An adhesive protective film prepared from a (meth)acrylic copolymer including the aromatic group-containing monomer may not achieve the above peel strength increase rate of Equation 1.

In an embodiment, the alkyl group-containing (meth)acrylate monomer and the hydroxyl group-containing (meth)acrylate monomer can be present in a total amount of 99 mol % or more, 99 mol % to 100 mol %, or 100 mol %, of the monomer mixture.

The (meth)acrylic copolymer may be prepared through polymerization of the monomer mixture by a polymerization method known to those skilled in the art. For example, the (meth)acrylic copolymer may be prepared by adding an initiator to the monomer mixture, followed by copolymer polymerization, for example, suspension polymerization, emulsion polymerization, solution polymerization, and the like. Polymerization may be performed at a temperature of 60° C. to 70° C. for 4 hours to 8 hours. The initiator may be selected from any typical initiators including azo-based polymerization initiators; and/or peroxides, such as benzoyl peroxide or acetyl peroxide.

### Curing Agent

The curing agent can be configured to thermally cure the (meth)acrylic copolymer to form the matrix of the adhesive protective film and can be configured to provide initial peel strength to the adhesive protective film.

The curing agent can include an isocyanate curing agent as a heat curing agent, in which the isocyanate curing agent is present in an amount of 6 parts by weight or more relative to 100 parts by weight of the (meth)acrylic copolymer. When the isocyanate curing agent is present in an amount of 6 parts by weight or more, preferably 7 parts by weight or more, the adhesive protective film can secure high peeling performance. For example, the isocyanate curing agent can be present in an amount of 6 parts by weight to 20 parts by weight, 7 parts by weight to 20 parts by weight, 7 parts by weight to 10 parts by weight, 8 parts by weight to 15 parts by weight, 8 parts by weight to 10 parts by weight, or 8 parts by weight to 10 parts by weight, relative to 100 parts by weight of the (meth)acrylic copolymer.

The isocyanate curing agent can include bi- or higher functional, specifically bi- to hexafunctional isocyanate curing agents. In one embodiment, the isocyanate curing agent can include at least one of a xylene diisocyanate (XDI) including m-xylene diisocyanate and the like, methylene bis(phenylisocyanate) (MDI) including 4,4′-methylene bis(phenylisocyanate) and the like, naphthalene diisocyanate, toluene diisocyanate, hexamethylene diisocyanate, isophorone diisocyanate, and adducts thereof. For example, the adducts can include a trimethylolpropane adduct of toluene diisocyanate, a trimethylolpropane adduct of hexamethylene diisocyanate, or a trimethylolpropane adduct of isophorone diisocyanate, trimethylolpropane adduct of xylene diisocyanate, isocyanurate of toluene diisocyanate, isocyanurate of hexamethylene diisocyanate, and isocyanurate of isophorone diisocyanate. The isocyanate curing agent can include at least one of the above compounds.

The curing agent can further include a metal chelate curing agent.

In one embodiment, the isocyanate curing agent and the metal chelate curing agent may be present at a weight ratio of 10:1 to 5:1 (isocyanate curing agent: metal chelate curing agent), for example, 10:1 to 6:1. In this range, the adhesive protective film can be configured to secure enhanced peeling performance.

The metal chelate curing agent can be any metal chelate curing agents and can include a curing agent including a metal, for example, aluminum, titanium, iron, copper, zinc, tin, titanium, nickel, antimony, magnesium, vanadium, chromium, zirconium, and the like. For example, the metal chelate curing agent can include at least one of aluminum ethyl acetoacetate diisopropylate, aluminum tris(ethyl acetoacetate), aluminum alkyl acetoacetate diisopropylate, aluminum isopropylate, mono-sec-butoxy aluminum diisopropylate, aluminum-sec-butyrate, aluminum ethylate, tetra-isopropyl titanate, tetra-n-butyl titanate, butyl titanate dimers, titanium acetyl acetonate, titanium octylene glycolate, titanium tetra-acetyl acetonate, titanium ethyl acetate, titanium polyhydroxystearate, and aluminum acetyl acetonate.

The metal chelate curing agent can be present in an amount of 3 parts by weight or more, specifically 0.001 parts by weight to 1 part by weight, more specifically 0.01 parts by weight to 1 part by weight, relative to 100 parts by weight of the (meth)acrylic copolymer. In this range, the metal chelate curing agent can be configured to provide additional effects without impairing the effects of the adhesive protective film according to the present disclosure.

The curing agent, for example, a mixture of the isocyanate curing agent and the metal chelate curing agent, an be present in an amount of 8 parts by weight to 20 parts by weight, specifically 8.5 parts by weight to 15 parts by weight, more specifically 8.5 parts by weight to 10.5 parts by weight, more specifically 8.5 parts by weight to 10 parts by weight, relative to 100 parts by weight of the (meth)acrylic copolymer. In this range, the adhesive protective film can be configured to exhibit improved reliability.

### Aromatic Group-Containing Mono- or Higher Functional Monomer

The aromatic group-containing mono- or higher functional monomer has at least one functional group capable of reacting with an aromatic group and an initiator. As used herein, the aromatic group may refer to a C₆ to C₅₀ monocyclic or polycyclic functional group. For example, the aromatic group may refer to a substituted or unsubstituted benzyl, phenyl, biphenyl, terphenyl, or naphthalenyl group, and the like. Furthermore, as used herein, the term “functional group” may refer to a vinyl group or a (meth)acrylate group, which may be effective in prevention of excessive shrinkage of the adhesive protective film upon curing by light irradiation.

The aromatic group-containing mono- or higher functional monomer can contribute to improvement in adhesion of the adhesive protective film to an adherend, for example, a plastic film having an aromatic group, particularly a polyimide-based film, by increasing attractive force of an adhesive layer of the adhesive protective film to the adherend through a stacking effect via a π-π bond to the adherend. The aromatic group is a bulkier substituent than a straight or branched alkyl group and can be inserted into a network type cured product of the (meth)acrylic copolymer and the curing agent, for example, an interpenetrating polymer network (IPN) structure or a semi-IPN structure, before light irradiation, thereby contributing to suppression of excessive increase in initial peel strength of the adhesive protective film with respect to the adherend.

The aromatic group-containing mono- or higher functional monomer can be configured to increase cohesion and/or modulus of the adhesive protective film after light irradiation. Accordingly, when the adhesive protective film attached to a surface of the adherend is cured by light irradiation, the adhesive protective film can be attached to the adherend with enhanced peel strength, whereby peel strength of the adhesive protective film can be increased.

It is desirable that the homopolymer glass transition temperature of the aromatic group-containing mono- or higher functional monomer be in a predetermined range relative to the glass transition temperature of the (meth)acrylic copolymer. This condition increases peel strength of the adhesive protective film after light irradiation by suppressing shrinkage of the adhesive protective film even when the adhesive protective film is cured by light irradiation. The homopolymer glass transition temperature of the aromatic group-containing mono- or higher functional monomer is greater than the glass transition temperature of the (meth)acrylic copolymer and a difference therebetween may be 20° C. or more, for example, 20° C. to 120° C., or 40° C. to 100° C. In this range, an increase in peel strength of the adhesive protective film after light irradiation can be expected.

The aromatic group-containing mono- or higher functional monomer may have a homopolymer glass transition temperature of 6° C. or more, for example, 6° C. to 50° C. In this range, the aromatic group-containing mono- or higher functional monomer has a greater glass transition temperature than the (meth)acrylic copolymer, thereby improving peel strength of the adhesive protective film through improvement in cohesion after light irradiation.

The aromatic group-containing mono- or higher functional monomer may include a compound represented by Formula 1 without being limited thereto:

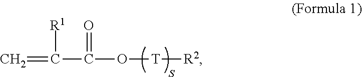

where R¹ is hydrogen or a methyl group, s is an integer of 0 to 10, R² is a substituted or unsubstituted C₆ to C₅₀ aryl group or a substituted or unsubstituted C₆ to C₅₀ aryloxy group, and T is a substituted or unsubstituted C₁ to C₆ alkylene group or a substituted or unsubstituted C₁ to C₆ alkyleneoxy group.

As used herein, “aryloxy” refers to an aryl group attached to an oxo group. The site of attachment to the parent moiety is via the oxo group.

As used herein, “alkyleneoxy” refers to an alkylene group attached to an oxo group. The site of attachment to the parent moiety is via the oxo group.

As used herein, “substituted” in the expression “substituted or unsubstituted” means that at least one hydrogen atom of a corresponding functional group is substituted with a C₁ to C₁₀ alkyl group, a C₁ to C₁₀ thioalkyl group, a C₁ to C₁₀ alkoxy group, a halogen (F, Cl, Br, or I), a C₃ to C₁₀ cycloalkyl group, or a C₆ to C₂₀ aryl group.

Specifically, R² may be a substituted or unsubstituted phenoxy group, benzyl group, phenyl group, biphenyl group, terphenyl group, naphthyl group, or the like. Specifically, the aromatic group-containing mono- or higher functional monomer can include at least one of phenoxy (meth)acrylate, 2-ethyl phenoxy (meth)acrylate, benzyl (meth)acrylate, phenyl (meth)acrylate, 2-ethyl thiophenyl (meth)acrylate, 2-phenylethyl (meth)acrylate, 3-phenylpropyl (meth)acrylate, 4-phenylbutyl (meth)acrylate, 2-(2-methylphenyl)ethyl (meth)acrylate, 2-(3-methylphenyl)ethyl (meth)acrylate, 2-(4-methylphenyl)ethyl (meth)acrylate, 2-(4-propylphenyl)ethyl (meth)acrylate, 2-(4-(1-methylethyl) phenyl)ethyl (meth)acrylate, 2-(4-methoxyphenyl)ethyl (meth)acrylate, 2-(4-cyclohexylphenyl)ethyl (meth)acrylate, 2-(2-chlorophenyl)ethyl (meth)acrylate, 2-(3-chlorophenyl)ethyl (meth)acrylate, 2-(4-chlorophenyl)ethyl (meth)acrylate, 2-(4-bromophenyl)ethyl (meth)acrylate, 2-(3-phenylphenyl)ethyl (meth)acrylate, o-biphenyl (meth)acrylate, m-biphenyl (meth)acrylate, p-biphenyl (meth)acrylate, 2,6-terphenyl (meth)acrylate, o-terphenyl (meth)acrylate, m-terphenyl (meth)acrylate, p-terphenyl (meth)acrylate, 4-(4-methylphenyl) phenyl (meth)acrylate, 4-(2-methylphenyl) phenyl (meth)acrylate, 2-(4-methylphenyl) phenyl (meth)acrylate, 2-(2-methylphenyl) phenyl (meth)acrylate, 4-(4-ethylphenyl) phenyl (meth)acrylate, 4-(2-ethylphenyl) phenyl (meth)acrylate, 2-(4-ethylphenyl) phenyl (meth)acrylate, 2-(2-ethylphenyl) phenyl (meth)acrylate, and mixtures thereof.

Preferably, the aromatic group-containing mono- or higher functional monomer can include at least one of benzyl (meth)acrylate, ethoxylated phenyl acrylate (phenyl(EO)1 acrylate, phenyl(EO)2 acrylate), ethoxylated phenylphenol acrylate (o-phenylphenol(EO) acrylate), phenoxy benzyl acrylate, biphenylmethyl acrylate, and naphthyl acrylates including 1-naphthyl acrylate, and the like.

Preferably, the aromatic group-containing mono- or higher functional monomer is phenoxybenzyl (meth)acrylate.

The aromatic group-containing mono- or higher functional monomer can be present in an amount of 120 parts by weight or more, for example, 120 parts by weight to 150 parts by weight, specifically 120 parts by weight to 130 parts by weight, relative to 100 parts by weight of the (meth)acrylic copolymer. In this range, the aromatic group-containing mono- or higher functional monomer can contribute to increase in peel strength of the adhesive protective film after light irradiation and can suppress shrinkage of the adhesive protective film.

### Initiator

The initiator is configured to cure the aromatic group-containing mono- or higher functional monomer to allow physical change of the adhesive protective film by light irradiation. The initiator can include at least one selected from among a photo-radical initiator and a cationic photoinitiator, and may further include a thermal initiator.

In an embodiment, the initiator may include a photoinitiator having a maximum absorption wavelength in the range of irradiation wavelengths applied during light irradiation. For example, the initiator may have a maximum absorption wavelength in the range of 280 nm to 430 nm. In this range, the initiator is configured to allow photo-curing of the aromatic group-containing mono- or higher functional monomer by light irradiation. Specifically, the photoinitiator can include a phosphorus-based initiator, a ketone-based initiator, and the like, without being limited thereto.

The initiator may be present in an amount of 0.01 parts by weight to 7.5 parts by weight, specifically 0.03 parts by weight to 4.5 parts by weight, relative to 100 parts by weight of the (meth)acrylic copolymer. In this range, the initiator can be configured to secure uniform curing for the aromatic group-containing mono- or higher functional monomer by light irradiation while preventing deterioration in transparency of the adhesive protective film due to residual initiator.

The adhesive composition can further include a curing accelerator.

The curing accelerator, during the curing reaction of the adhesive protective film, can be configured to to further improve cohesion of an adhesive layer. The curing accelerator can include curing accelerators known to those skilled in the art. The curing accelerator can include a tin-based metal compound, a zinc-based metal compound, an amine-based compound, a titanium-based metal compound, a bismuth-based metal compound, and an aluminum-based metal compound. Among these compounds, tin-based metal compounds are preferably used. For example, the tin-based metal compounds can include tetra- or bivalent organotin-based compounds, such as dibutyltin dilaurate, bis-acetylacetonate-dibutyltin, dibutyltin dimaleate, dibutyltin dimaleate, and the like.

The curing accelerator may be present in an amount of 0.001 parts by weight to 3 parts by weight relative to 100 parts by weight of the (meth)acrylic copolymer. In this range, the curing accelerator can be configured to accelerate curing of the adhesive protective film while improving cohesion of the adhesive film.

The adhesive composition can further include a silane coupling agent.

The silane coupling agent can be configured to further increase peel strength of the adhesive protective film. The silane coupling agent can include silane coupling agents known to those skilled in the art. For example, the silane coupling agent can include epoxy group-containing silane coupling agents, such as glycidoxypropyltrimethoxysilane, glycidoxypropylmethyldimethoxysilane, and the like, without being limited thereto.

The silane coupling agent may be present in an amount of 0.01 parts by weight to 5 parts by weight relative to 100 parts by weight of the (meth)acrylic copolymer. In this range, the silane coupling agent can be configured to further increase peel strength of the adhesive protective film.

The adhesive composition can further include additives. The additives can include additives for adhesive protective films known to those skilled. For example, the additives can include at least one selected from among pigments, UV absorbents, antioxidants, leveling agents, antistatic agents, retardation agents, catalysts, and reworking agents, without being limited thereto.

The adhesive composition can further include a solvent. The solvent can be configured to increase workability of the adhesive composition to form an adhesive protective film having a thin thickness and a uniform surface. The solvent can include solvents known to those skilled in the art. For example, the solvent can include methyl ethyl ketone, methyl isobutyl ketone, ethyl acetate, toluene, and the like, without being limited thereto. In one embodiment, the adhesive composition may have a solid content of 15 wt % to 40 wt %, specifically 20 wt % to 30 wt %, in terms of solid content of the adhesive protective film. In this range, the composition can be configured to have good coatability.

The adhesive protective film may have a haze of 5% or less, specifically 0.1% to 2%, and a total transmittance of 80% or more, specifically 85% to 95%, in the visible spectrum (for example, at a wavelength of 380 nm to 780 nm). In this range, the adhesive protective film can be configured to have good optical transparency and can be used in an optical display apparatus.

The adhesive protective film may have an adhesive layer thickness of 200 μm or less, specifically greater than 0 μm to less than or equal to 100 μm, more specifically 5 μm to 50 μm. In this range, the adhesive protective film can be configured to provide a protective effect for a flexible panel.

The adhesive protective film can further include a base film on one surface thereof.

The adhesive protective film can further include a release film on the other surface thereof.

An aspect of the present disclosure relates to an optical member.

The optical member can include a polyimide-based optical device containing polyimide ash on at least one surface thereof and an adhesive layer attached to the polyimide ash-containing surface. The adhesive layer can include a phot cured product of the adhesive protective film.

In an embodiment, the polyimide-based optical device can be based on a flexible substrate. The flexible substrate can be configured to support an optical device, such as an organic light emitting diode and the like.

An optical device can be further stacked on at least one surface of the polyimide-based optical device. Such an optical device can be configured to provide conductivity and/or optical functions, for example, light emission, polarization, optical compensation, and display quality improvement, to an optical display apparatus. For example, the optical device can include a window film, a window, a polarizing plate, a color filter, a retardation film, an elliptical polarizing film, a reflective polarizing film, an antireflection film, a compensation film, a brightness enhancement film, an alignment film, a light diffusion film, a glass-shatterproof film, a surface protection film, an OLED device barrier layer, a plastic LCD substrate, a transparent electrode film including indium tin oxide (ITO), fluorinated tin oxide (FTO), aluminum-doped zinc oxide (AZO), carbon nanotubes (CNT), Ag nanowires, or graphene, and the like.

The adhesive layer can include a photo-cured product of the adhesive protective film. The adhesive protective film can be substantially the same as the adhesive protective film.

In an embodiment, the adhesive layer can be patterned.

A protective layer can be further stacked on at least one surface of the adhesive layer.

The protective layer can be configured to protect the adhesive layer or the polyimide-based optical device. The protective layer is not limited to a particular kind so long as the protective layer is optically transparent and is capable of providing flexibility. For example, the protective layer can include a polyester film including a polyethylene terephthalate film, a polyethylene naphthalate film, a polycarbonate film, a polyether sulfone film, and the like.

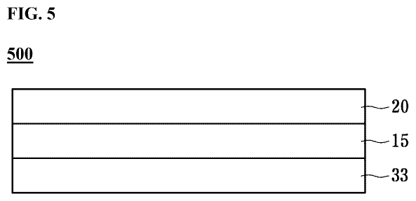

FIG. 5 is a cross-sectional view of an optical member 500 according to one embodiment. Referring to FIG. 5, the optical member 500 may include a polyimide-based optical device 15 having polyimide ash on a lower surface thereof, an optical device 20 formed on an upper surface of the polyimide-based optical device 15, and an adhesive layer 33 formed on a lower surface of the polyimide-based optical device 15.

An aspect of the present disclosure relates to an optical display apparatus.

The optical display apparatus can include a cured product of the adhesive protective film or the optical member. The cured product can be a photo-cured product.

The optical display apparatus can include an organic light emitting diode display, a liquid crystal display, or the like. The optical display apparatus can include a flexible display device. The optical display apparatus can also include a non-flexible display apparatus.

### EXAMPLES

the present disclosure is described in more detail with reference to the following examples. However, it should be understood that these examples are provided for illustration only and should not be construed in any way as limiting the disclosure.

### Preparative Example

A solvent (ethyl acetate) was added to a 1 L reactor under a nitrogen gas atmosphere and provided with a cooling device to facilitate temperature control. 100 parts by weight of a monomer mixture including 97 mol % of n-butyl acrylate (homopolymer glass transition temperature: −45° C.) and 3 mol % of 4-hydroxybutyl acrylate were added to the reactor. Nitrogen gas was added to the monomer mixture for 30 min to remove oxygen and the temperature of the reactor was maintained at 62° C. While uniformly stirring the monomer mixture, 0.07 wt % of an initiator (azobisisobutyronitrile) was added to the monomer mixture and reacted at 62° C. for 8 hours to prepare a (meth)acrylic copolymer (weight average molecular weight: 1,000,000 g/mol). A (meth)acrylic copolymer solution (24% by weight in terms of solid content) was prepared by adding ethyl acetate as a solvent to the resulting product.

### Example 1

In terms of solid content, an adhesive composition (25 wt %) was prepared by adding TD-75 (isocyanate curing agent, isocyanate reactive type, 75 wt %, Soken Co., Ltd.) and BXX-4805 (aluminum chelate curing agent, 5 wt %, Samyoung Ink Co., Ltd.) as curing agents, phenoxybenzyl acrylate (homopolymer glass transition temp: 6° C., Hannong Chemical Co., Ltd.) as an aromatic group-containing monofunctional monomer, and Irgacure TPO (phosphorus photoinitiator, BASF) as a photoinitiator to 100 parts by weight of the (meth)acrylic copolymer prepared in Preparative Example in amounts listed in Table 1, followed by diluting a resulting solution in methyl ethyl ketone.

The prepared adhesive composition was deposited to a thickness of 13 μm on an antistatic layer-coated surface of a base film (polyethylene terephthalate (PET) film, T914J75, thickness: 75 μm, with an antistatic layer coated on one surface, MCC) and was dried at 110° C. for 4 min to form an adhesive layer. Then, a release film (thickness: 25 μm, with one surface subjected to silicone release treatment, MHF25, MCC) was layered to the adhesive layer and left at 50° C. for 3 days, thereby preparing an adhesive protective film-containing sheet in which the adhesive protective film (thickness: 13 μm) and the release film are sequentially stacked on the base film.

### Examples 2 to 4

Adhesive protective film-containing sheets were prepared in the same manner as in Example 1 except that the type and/or content of each component in Example 1 was changed as shown in Table 1.

### Comparative Examples 1 to 5

Adhesive protective film-containing sheets were prepared in the same manner as in Example 1 except that the type and/or content of each component in Example 1 was changed as shown in Table 1.

The adhesive protective film-containing sheets prepared in Examples and Comparative Examples were evaluated as to the following properties and evaluation results are shown in Table 1.

### Reference Example: Preparation of Polyimide Layer Having Polyimide Ash on One Surface

A polyimide layer having polyimide ash on one surface was prepared.

A polyimide varnish (SD Flex, DuPont) was deposited to a thickness of 20 μm on an upper surface of an alkali-free glass plate (thickness: 1.1 mm) using a doctor blade coating device (gauge diameter: 0.65 mm) to prepare a polyimide varnish coat.

The polyimide varnish coat was subjected to heat treatment at 80° C. for 10 min and at 120° C. for 20 min to prepare a dry film (thickness: 20 μm) of the polyimide varnish coat.

A laminate of the polyimide layer (thickness: 20 μm) and the glass plate was prepared by curing the dried polyimide varnish layer in a chamber at 250° C. for 60 min.

The laminate was irradiated with a laser beam(s) while moving a laser irradiation device (MicroLAS, COHERENT) placed above the glass plate of the laminate from one side to the other side. Laser irradiation was performed under conditions of wavelength: 308 nm, femtosecond, dose: 170 mJ/cm².

After placing the laminate at room temperature for 1 hour, a polyimide layer having polyimide ash on one surface was prepared by removing the glass plate.

(1) Initial peel strength (unit: gf/inch):

Only the release film was peeled off of each of the adhesive protective film-containing sheets of Examples and Comparative Examples to expose the adhesive protective film. The exposed surface of the adhesive protective film was attached to the polyimide ash-containing surface of the polyimide layer. Then, a specimen was prepared by pressing a attached product under a 2 kg load roll and cutting the pressed product to a size of 25 mm×100 mm (width×length). The specimen was a laminate of the PET film, the adhesive protective film and the polyimide layer having polyimide ash.

The specimen was placed at 23° C. and 50% RH (relative humidity) for 30 min. Pursuant to JISZ2037, the peel strength of the adhesive protective film was measured when the adhesive protective film was peeled off of the polyimide ash-containing surface using a tensile tester (Texture Analyzer, TA Industry) by a peel strength measurement method under conditions of peeling temperature: 25° C., peeling speed: 2,400 mm/min, and peeling angle: 180°.

(2) Peel strength after UV irradiation (unit: gf/inch):

A specimen was prepared in the same manner as in (1).

The specimen was placed at 23° C. and 50% RH for 30 min. The specimen was irradiated with UV light at a dose of 1,000 mJ/cm² and at a wavelength of 385 nm using a UV LED irradiator (SUV-L5160A, UVSMT) at the PET film side then placed at 23° C. and 50% RH for 30 min. Pursuant to JISZ2037, the peel strength of the adhesive protective film was measured when the adhesive protective film was peeled off of the polyimide ash-containing surface using a tensile tester (Texture Analyzer, TA Industry) by a peel strength measurement method under conditions of peeling temperature: 25° C., peeling speed: 2,400 mm/min, and peeling angle: 180°.

(3) Peeling performance (unit: %):

Only the release film was peeled off of each of the adhesive protective film-containing sheets of Examples and Comparative Examples to expose the adhesive protective film. The exposed surface of the adhesive protective film was attached to the polyimide ash-containing surface of the polyimide layer. Then, a specimen was prepared by pressing the attached product under a 2 kg load roll and cutting the pressed product to a size of 100 mm×100 mm (width×length).

In the specimen, the adhesive protective film was subjected to patterning through laser irradiation. Patterning was performed by irradiating the adhesive protective film with a laser beam(s) at intervals of 1 cm in both the longitudinal and transverse directions of the adhesive protective film. Then, when the adhesive protective film was partially removed by an adhesive tape or pincers, the number of pieces that were selectively peeled off at the same time without deformation of the polyimide ash-containing surface or the polyimide layer and without dragging between pieces to be peeled off and pieces not to be peeled off was counted. A greater number indicates better peeling performance.

(4) Durability after light irradiation:

Only the release film was peeled off of each of the adhesive protective film-containing sheets of Examples and Comparative Examples to expose the adhesive protective film. The exposed surface of the adhesive protective film was attached to the polyimide ash-containing surface of the polyimide layer. The attached product was pressed under a 2 kg load roll and cut to a size of 150 mm×90 mm (length×width). Then, the pressed product was left at 23° C. and 50% RH for 30 min, followed by pressure application thereto. The resulting product was irradiated with UV light at a dose of 1,000 mJ/cm² and at wavelength of 365 nm using a UV LED irradiator (SUV-L5160A, UVSMT) at the PET film side and was left at 23° C. and 50% RH for 30 min, thereby preparing a specimen.

The prepared specimen was evaluated for heat resistance and humid heat resistance. Heat resistance was evaluated by observing the occurrence of bubbles or delamination after the specimen was left at a temperature of 85° C. for 500 hours. Humid heat resistance was evaluated by observing the occurrence of bubbles or delamination after the specimen was left at a temperature of 60° C. and 95% RH for 500 hours. The evaluation standard is shown as follows. Generation of bubbles or delamination between the adhesive protective film and the polyimide ash-containing surface was evaluated with the naked eye.
⊚: No bubbles or spots
○: 1 bubble or spot
Δ: Two or three bubbles or spots
x: More than 3 bubbles or spots
(5) Bubble generation when attached to polyimide layer

Only the release film was peeled off of each of the adhesive protective film-containing sheets of Examples and Comparative Examples to expose the adhesive protective film. The exposed surface of the adhesive protective film was attached to the polyimide ash-containing surface of the polyimide layer. Generation of bubbles or delamination between the adhesive protective film and the polyimide ash-containing surface was evaluated with the naked eye. No bubbles was evaluated as “good” and the existence of bubbles was evaluated as “poor.”

TABLE 1

| | Example | | | | Comparative Example | | | | |
|---|---|---|---|---|---|---|---|---|---|
| | 1 | 2 | 3 | 4 | 1 | 2 | 3 | 4 | 5 |
| (Meth)acrylic copolymer | 100 | 100 | 100 | 100 | 100 | 100 | 100 | 100 | 100 |
| Isocyanate curing agent | 6.3 | 7.8 | 9.4 | 8 | 2.8 | 3.8 | 4.7 | 6.3 | 5 |
| Metal chelate curing agent | 1 | 1 | 1 | 1 | 1 | 1 | 1 | 1 | 1 |
| Aromatic group-containing | 120 | 130 | 120 | 120 | 80 | 80 | 80 | 90 | 120 |
| monomer | | | | | | | | | |
| Photoinitiator | 0.6 | 0.6 | 0.6 | 0.6 | 0.6 | 0.6 | 0.6 | 0.6 | 0.6 |
| Initial peel strength | 6.2 | 5.3 | 4.7 | 5.8 | 12.5 | 8.8 | 7.7 | 7.3 | 7.5 |
| Peel strength after UV | 465 | 445 | 335 | 402 | 304 | 219 | 192 | 346 | 478 |
| irradiation | | | | | | | | | |
| Ratio in Equation 1 | 75 | 84.0 | 71.3 | 69.3 | 24.3 | 24.9 | 24.9 | 47.4 | 63.7 |
| Peeling performance | 90 | 95 | 96 | 93 | 50 | 56 | 60 | 67 | 65 |
| Durability | ⊚ | ⊚ | ⊚ | ⊚ | ⊚ | ⊚ | ◯ | ⊚ | ⊚ |
| Generation of bubbles | Good | Good | Good | Good | Good | Good | Good | Good | Good |

As shown in Table 1, the adhesive protective films according to the present disclosure exhibited excellent peeling performance when attached to a polyimide-based optical device. The adhesive protective films according to the present disclosure can be secured to a polyimide-based optical device having polyimide ash with greater peel strength after light irradiation than before light irradiation, thereby improving durability of the optical device. The adhesive protective films according to the present disclosure can be configured to prevent generation of bubbles when attached to the polyimide-based optical device having polyimide ash. The adhesive protective films according to the present disclosure can be used both as a temporary protective film for processes on a flexible light emitting device panel substrate and as a protective film for pattern reinforcement that can be selectively peeled off to form a pattern.

It should be understood that various modifications, changes, alterations, and equivalent embodiments can be made by those skilled in the art without departing from the spirit and scope of the disclosure.

What is claimed is:

1. An adhesive protective film comprising a cured product of a composition comprising:
a (meth)acrylic copolymer;
a curing agent;
an aromatic group-containing mono- or higher functional monomer; and
a photoinitiator,
wherein the adhesive protective film has an initial peel strength of 7 gf/inch or less relative to a polyimide ash-containing surface configured to be attached thereto, and wherein the adhesive protective film has a peel strength of 200 gf/inch or more relative to the polyimide ash-containing surface upon light irradiation.

2. The adhesive protective film as claimed in claim 1, wherein the curing agent comprises an isocyanate curing agent, wherein the isocyanate curing agent is present in an amount of 6 parts by weight or more relative to 100 parts by weight of the (meth)acrylic copolymer.

3. The adhesive protective film as claimed in claim 2, wherein the curing agent further comprises a metal chelate curing agent.

4. The adhesive protective film as claimed in claim 3, wherein the isocyanate curing agent and the metal chelate curing agent are present at a weight ratio of 10:1 to 5:1.

5. The adhesive protective film as claimed in claim 1, wherein the aromatic group-containing mono- or higher functional monomer is present in an amount of 120 parts by weight or more relative to 100 parts by weight of the (meth)acrylic copolymer.

6. The adhesive protective film as claimed in claim 1, wherein the aromatic group-containing mono- or higher functional monomer has a homopolymer glass transition temperature of 6° C. or more.

7. The adhesive protective film as claimed in claim 1, wherein the aromatic group-containing mono- or higher functional monomer comprises a compound represented by Formula 1: 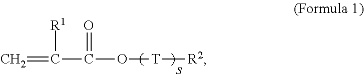
where
R¹ is hydrogen or a methyl group,
s is an integer of 0 to 10,
R² is a substituted or unsubstituted C₆ to C₅₀ aryl group or a substituted or unsubstituted C₆ to C₅₀ aryloxy group, and
T is a substituted or unsubstituted C₁ to C₆ alkylene group or a substituted or unsubstituted
C₁ to C₆ alkyleneoxy group.

8. The adhesive protective film as claimed in claim 1, wherein the (meth)acrylic copolymer comprises a copolymer of a monomer mixture comprising an alkyl group-containing (meth)acrylic monomer and a hydroxyl group-containing (meth)acrylic monomer.

9. The adhesive protective film as claimed in claim 8, wherein the monomer mixture comprises 90 mol % or more of a (meth)acrylic monomer, wherein the (meth)acrylic monomer has a homopolymer glass transition temperature of −80° C. to 0° C.

10. The adhesive protective film as claimed in claim 1, wherein the composition comprises 100 parts by weight of the (meth)acrylic copolymer, 8 parts by weight to 20 parts by weight of the curing agent, 120 parts by weight or more of the aromatic group-containing mono- or higher functional monomer, and 0.01 parts by weight to 7.5 parts by weight of the photoinitiator.

11. The adhesive protective film as claimed in claim 1, wherein the adhesive protective film has a peel strength increase rate of 65 or more, as calculated according to Equation 1:
Peel strength increase rate=P2/P1,
where P1 is the initial peel strength and P2 is the peel strength.

12. An optical member comprising a polyimide-based optical device comprising:
a polyimide ash-containing surface comprising a polyimide ash on at least one surface of the polyimide-based optical device; and
an adhesive layer layered to the polyimide ash-containing surface, wherein the adhesive layer comprises the adhesive protective film of claim 1.

13. An optical display apparatus comprising the optical member as claimed in claim 12.
